(19) United States
(12) Patent Application Publication
(10) Pub. No.: US 2020/0083385 A1
(43) Pub. Date: Mar. 12, 2020

(54) METHOD FOR PROCESSING DISPLAY PANEL, AND DISPLAY PANEL

(71) Applicants: CHONGQING HKC OPTOELECTRONICS TECHNOLOGY CO.,LTD., Chongqing (CN); HKC CORPORATION LIMITED, Shenzhen (CN)

(72) Inventors: Kaijun Liu, Chongqing (CN); Entsung Cho, Chongqing (CN)

(21) Appl. No.: 16/311,573

(22) PCT Filed: Oct. 22, 2018
(86) PCT No.: PCT/CN2018/111259

§ 371 Date: Dec. 19, 2018

(30) Foreign Application Priority Data
Sep. 12, 2018 (CN) 201811060540.3

(51) Int. Cl. H01L 29/786; H01L 27/12; H01L 29/423; H01L 29/49

(52) U.S. Cl. CPC H01L 29/78633; H01L 27/1218; H01L 27/1222; H01L 27/1225; H01L 27/127; G02F 1/1368; H01L 29/42384; H01L 29/4908; H01L 29/78669; H01L 29/78678; H01L 29/7869; H01L 27/1292

(57) ABSTRACT

A method for processing a display panel includes: preparing a substrate (10), forming a first metal layer (20) on the substrate (10), forming a light shielding layer (30) attached to the substrate (10) at a lateral side of the first metal layer (20)

### CROSS-REFERENCE TO RELATED APPLICATIONS

This application is the International Application No. PCT/CN2018/111259 for entry into US national phase with an international filing date of Oct. 22, 2018, designating US, now pending, and claims priority to Chinese Patent Application No. 201811060540.3, filed on Sep. 12, 2018, the content of which is incorporated herein by reference in its entirety.

### BACKGROUND OF THE INVENTION

### Field of the Invention

The present application relates to the technical field of display, and particularly relates to a method for processing a display panel and a display panel.

### Description of Related Art

At present, each pixel of a TFT-LCD (Thin Film Transistor-Liquid Crystal Display) is mainly controlled by one TFT (Thin Film Transistor) switch, and the gates of the TFT switches are connected together to form a gate line, and the source layers of the TFT switches are connected together to form a signal line. When a voltage is applied to a gate layer G (Gate) of the TFT, the TFT may be brought into a conducting state, and the display data is able to pass through the signal line and the conducting TFT to arrive a drain layer D (Drain) of the TFT, thus forming an electric field on the pixel and charging the liquid crystal to achieve a display effect.

Usually, it is better when the on-state current of the TFT of an ideal TFT-LCD display is larger, and the off-state current of the TFT of an ideal TFT-LCD display is smaller. In order to prevent the leakage current from increasing due to backlight illumination, existing TFT-LCDs adopt a bottom gate structure to prevent an increase in the leakage current caused by the backlight directly illuminating the channel. However, the capacitance of the gate and the source/drain layer of the bottom gate structure is relatively large, an excessive parasitic capacitance not only causes erroneous writing of the pixel voltage, but also increases the drift of the threshold voltage Vth (Threshold voltage), and severe Vth drift will lead to the appearance of afterimages.

### BRIEF SUMMARY OF THE INVENTION

The purpose of the present application is to provide a method for processing a display panel, and is aimed at solving the problem how to decrease the parasitic capacitance disposed between two sides of the gate layer.

The present application is implemented in a way that, a method for processing a display panel, which includes the following steps of:

preparing a substrate;

forming a first metal layer on the substrate;

forming a light shielding layer attached to the substrate at a lateral side of the first metal layer;

forming an insulation layer on the first metal layer, the light shielding layer and the substrate, wherein the first metal layer and the light shielding layer are each disposed between the insulation layer and the substrate;

forming a semiconductor layer on the insulation layer;

forming a second metal layer on the semiconductor layer, wherein the semiconductor layer is disposed between the insulation layer and the second metal layer;

processing the second metal layer and the semiconductor layer to form a channel, wherein the channel divides the second metal layer into a source layer and a drain layer;

forming a protection layer on the source layer, the drain layer and an inner wall of the channel; and

forming a conductive layer on the protection layer, such that the conductive layer is connected with the source layer or the drain layer.

The present application further provides a display panel, the display panel is fabricated through the above method for processing a display pane.

Two sides of the first metal layer are coated with the light shielding layer in the present application. The light shielding layer can not only effectively shield light, prevent or reduce the generation of the leakage current; and because the light shielding layer can replace a part of the gate electrodes to provide shading, the width of the gate electrodes can be set to be smaller; meanwhile the light shielding layer has the property of insulation, the parasitic capacitances among the gate electrodes, the source electrodes and the drain electrodes may be reduced, thereby avoiding accidental writing of the pixel voltage caused by the excessive parasitic capacitance. At the same time, the drift of Vth under the impact of the bias voltage may be reduced, and the probability of image sticking is reduced.

### BRIEF DESCRIPTION OF THE DRAWINGS

In order to more clearly illustrate the technical solutions in the embodiments of the present application, the drawings used in the description of the embodiments will be briefly described below. Obviously, the drawings in the following description are some embodiments of the present application, and those skilled in the art may also obtain other drawings based on these drawings without paying any creative work.

FIG. 1 is a flow chart of a method for processing a display panel provided by an embodiment of the present application.

FIG. 2A is a process diagram of the step of S1 in FIG. 1.

FIG. 2B is a process diagram of the step of S2 in FIG. 1.

FIG. 2C is a process diagram of the step of S3 in FIG. 1.

FIG. 2D is a process diagram of the step of S4 in FIG. 1.

FIG. 2E is a process diagram of the step of S5 in FIG. 1.

FIG. 2F is a process diagram of the step of S6 in FIG. 1.

FIG. 2G is a process diagram of the step of S7 in FIG. 1.

FIG. 2H is a process diagram of the step of S8 in FIG. 1.

FIG. 2I is a process diagram of the step of S9 in FIG. 1.

### EMBODIMENTS OF THE PRESENT INVENTION

In order to make those skilled in the art better understand the solutions of the present application, the technical solutions in the embodiments of the present application are clearly described in the following with reference to the accompanying drawings in the embodiments of the present application. It is obvious that the described embodiments are only partial embodiments of the present application, and are not all embodiments. Based on the embodiments of the present application, all other embodiments obtained by those skilled in the art without any creative work should fall within the scope of the present application.

The term “include/comprise” and its any variation in the description, claims and accompany drawings of the present application are intended to cover a non-exclusive inclusion. For example, a process, a method or a system, a product or a device including a series of steps or units is not limited to the listed steps or units, but alternatively further includes steps or units not listed, or alternatively further includes other steps or units inherent to the process, method, product or device. Moreover, the terms “first”, “second” and “third” etc. are used to distinguish different objects, and are not intended to describe a particular order.

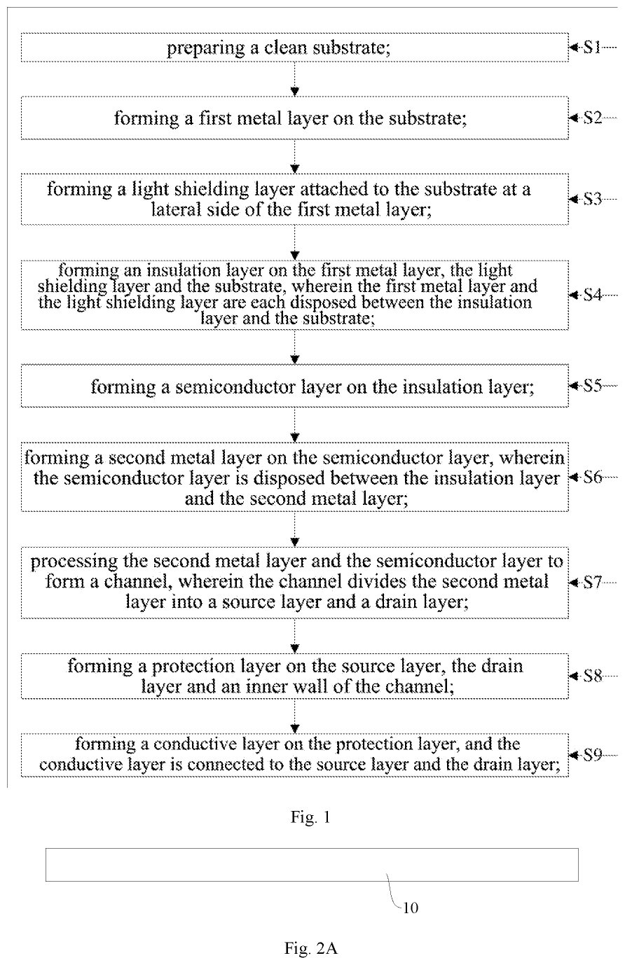

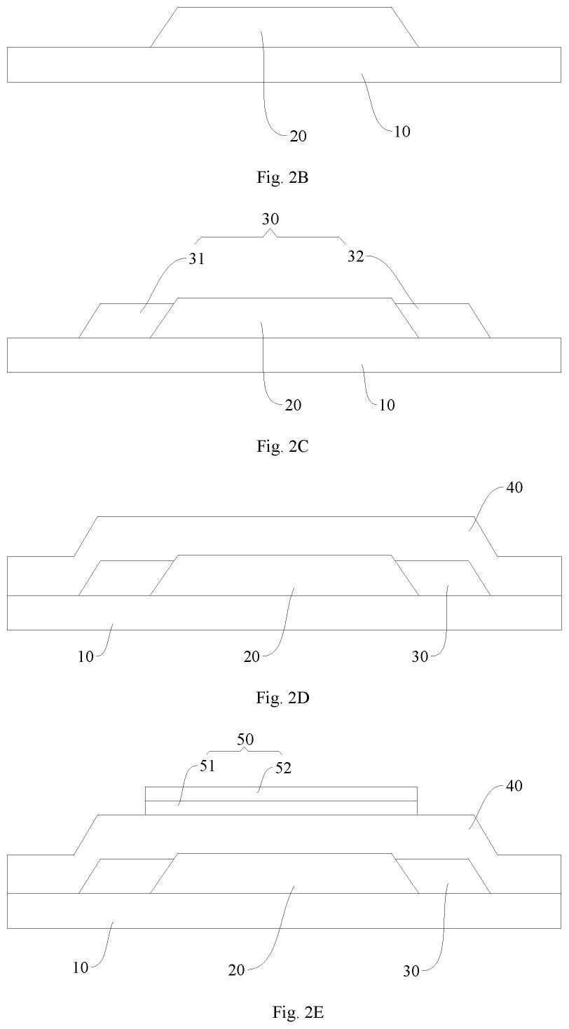

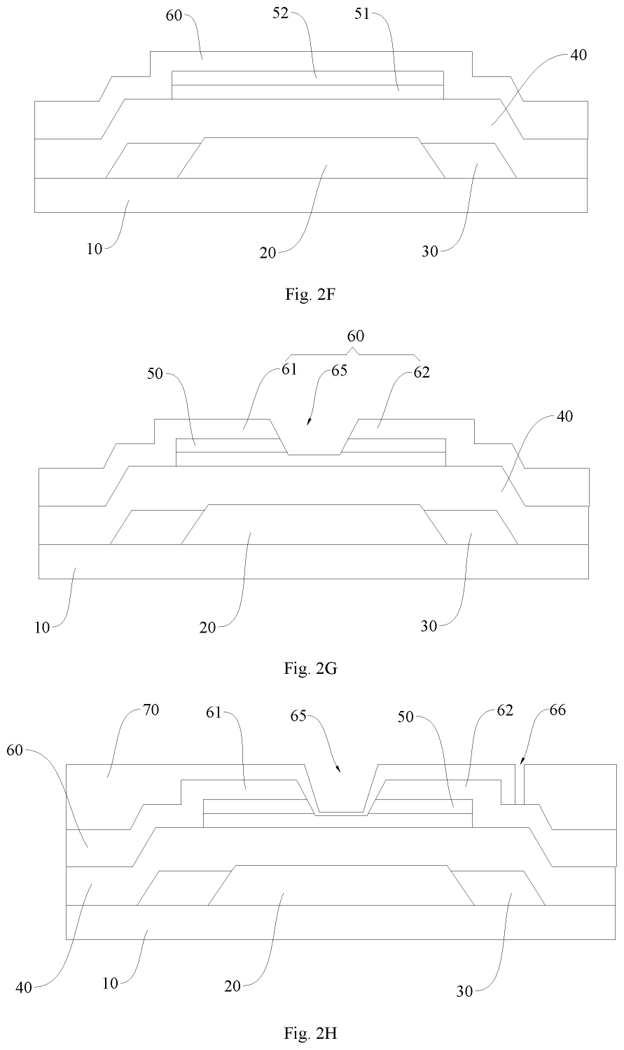

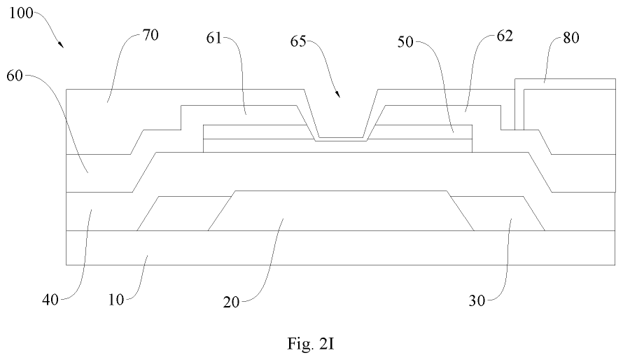

With reference to FIG. 1 and FIG. 2I, an embodiment of the present application provides a method for processing a display panel, and a display panel 100 produced through the method.

With reference to FIG. 1 and FIGS. 2A-2I, a method for processing a display panel 100 includes the following steps:

S1: preparing a clean substrate 10;

alternatively, the substrate 10 is generally a glass substrate 10, and the thickness of the glass substrate 10 generally ranges from 0.52 mm to 0.58 mm.

S2: fabricating a first metal layer 20, and processing the first metal layer 20 to form a gate metal layer;

alternatively, sputtering on the substrate 10 and forming the first metal layer 20, and processing the first metal layer 20 to form the gate metal layer through processes such as exposure, development and the like.

S3: forming a light shielding layer 30 attached to the substrate 10 at a lateral side of the first metal layer 20;

it should be understood that the light shielding layer 30 is also known as the black matrix, and the material of the black matrix is a chromium-containing metal composition or a resin composition, the light shielding layer is an insulating light shielding layer. Alternatively, the light shielding layer 30 is coated on the side of the first metal layer 20.

S4: forming an insulation layer 40 on the first metal layer 20, the light shielding layer 30 and the substrate 10;

alternatively, the insulting layer 40 is disposed on the gate metal layer, so as to form a gate insulation layer. The first metal layer 20 and the light shielding layer are each disposed between the insulation layer 40 and the substrate 10; the insulation layer 40 completely covers the light shielding layer 30 and the first metal layer 20, and at least part of both two sides of the insulation layer 40 are contacted with the glass substrate 10.

S5: forming a semiconductor layer 50 on the insulation layer 40;

alternatively, the semiconductor layer 50 is formed by sputtering and coating.

S6: forming a second metal layer 60 on the semiconductor layer 50, and the semiconductor layer 50 is disposed between the insulation layer 40 and the second metal layer 60;

alternatively, the second metal layer 60 is formed through the process of sputtering.

S7: processing the second metal layer 60 and the semiconductor layer 50 to form a channel 65;

specifically, the channel 65 separates the second metal layer 60 into a source layer 62 and a drain layer 61; the processing procedures include the processes of exposure, development, and two wet Oxidation, and the process of two dry Oxidation. The probability of light entering the channel 65 is reduced through the light shielding layer 30 coated on the two sides of the first metal layer 20, thus reducing the leakage current.

The light shielding layer 30 may effectively block the passage of light, thereby reducing the projection of the backlight on the semiconductor layer, and avoiding an increase in leakage current. The light shielding layer 30 may further replace light shielding effect of partial first metal layer 20, and may appropriately reduce the width of the gate electrode, reduce the capacitance among the gate electrode, the source electrode and the drain electrode, prevent the pixel voltage from being erroneously written, and meanwhile prevent a short circuit among the source layer 62, the drain layer 61 and the gate metal layer, which improves the qualification rate of the display panel 100.

S8: forming a protection layer 70 on the source layer 62, the drain layer 61 and the inner walls of the channel 65;

alternatively, the protection layer 70 is a passivation layer, and the material of the passivation layer is silicon oxide or silicon nitride, and the protection layer 70 has an insulation protection effect.

S9: forming a conductive layer 80 on the protection layer 70, such that the conductive layer 80 is connected to the source layer 62 or the drain layer 61.

alternatively, the surface of the protection 70 is processed to form a contact hole 66, and the contact hole 66 connects the source layer 62 or the drain layer 61;

alternatively, the contact hole 66 is formed by the technologies of exposure and development.

With reference to FIGS. 2H to 2I, the conductive layer 80 is formed on the source layer 62, and the conductive layer 80 is connected to the source layer 62 through the contact hole 66. The conductive layer 80 is formed by sputtering on the protection layer 70 by a PVD (Physical Vapor Deposition) technology, and is connected to the source layer 62 through the contact hole 66. The material of the conductive layer is preferably ITO (Indium Tin Oxide).

Two sides of the first metal layer 30 are coated with the light shielding layer 30 in the present application. The light shielding layer 30 may not only effectively shield light, prevent or reduce the generation of the leakage current; and due to the insulation property of the light shielding layer 30, the parasitic capacitance among the first metal layer 20, the source electrode and the drain electrode may be reduced, thereby avoiding accidental writing of the pixel voltage caused by the excessive parasitic capacitance. At the same time, the drift of Vth under the impact of the bias voltage may be reduced, and the probability of image sticking is reduced.

With reference to FIGS. 2A to 2C, the light shielding layer 30 is formed by jet printing on the lateral side of the first metal layer 20 through an Inkjet technology. Alternatively, the Inkjet technology is an inkjet printing display production technology, which differs from conventional evaporation methods. The Inkjet technology has excellent properties, such as: reduction of panel defects due to particle contamination, high material utilization rate (the material utilization rate >90%), and no requirement for a metal mask, which is suitable for producing a large-sized display panel 100, and may greatly reduce the production cost of the display panel 100.

The light shielding layer 30 includes a first light shielding layer 31 which is formed on one side of the first metal layer 20 through jet printing and a second light shielding layer 32 which is formed on the other side of the first metal layer 20 through jet printing. The thickness of the first light shielding layer 31 is smaller than the thickness of the first metal layer 20, and the thickness of the second light shielding layer 32 is smaller than the thickness of the first metal layer 20, such that the first metal layer 20 may be in contact with the insulation layer 40, thereby making the insulation layer stably cover the first metal layer 20 and the light shielding layer and be less likely to occur relative movement. The first metal layer 20 is disposed between the first light shielding layer 31 and the second light shielding layer 32.

With reference to FIGS. 2D to 2G, the materials of the first metal layer 20 and the second metal layer 60 are one or more type of aluminum and molybdenum. Due to light weight and corrosion-resistant, the aluminum is widely used for its light weight, good electrical conductivity and thermal conductivity, high reflectivity and oxidation resistance, and is rich in resources, therefore having low cost. The molybdenum or molybdenum alloy may achieve good adhesion, and may maintain good consistency with the glass substrate 10 in thermal expansion, which is convenient in material selection and mature in production technology. When the materials of the first metal layer 20 and the second metal layer 60 are aluminum, the thickness of the first metal layer 20 and the second metal layer 60 ranges from 3240 angstrom to 3960 angstrom. When the materials of the first metal layer 20 and the second metal layer 60 are molybdenum, the thickness of the first metal layer 20 and the second metal layer 60 ranges from 450 angstrom to 550 angstrom.

The material of the insulation layer 40 includes one or more type of silicon oxide and silicon nitride. Both silicon oxide and silicon nitride are characterized by high hardness, wear resistance, and oxidation resistance in high temperature.

The semiconductor layer 50 includes: an active layer 51 formed on the insulation layer 40 and an ohmic contact layer 52 formed on the active layer 51 and blocked by the channel 65. Alternatively, the active layer 51 is an I-a-Si thin film layer, and the ohmic contact layer 52 is an N+a-Si thin film layer. The ohmic contact layer 52 is divided into two portions by the channel 65, with a portion between the active layer 51 and the drain layer 61 and another portion between the source layer 62 and the active layer 51. The material of the active layer 51 is amorphous silicon or polycrystalline silicon.

Alternatively, the protection layer 70 is formed through a chemical vapor deposition film formation technology, and the material of the protection layer 70 includes one or more type of silicon oxide and silicon nitride. The chemical vapor deposition film formation technology is actually chemical vapor deposition, and this technology may be used to coat at a surface to be processed to form a film layer.

The above description is only alternative embodiments of the present application, and is not intended to limit the present application. Any modifications, equivalent substitutions and improvements etc. made within the spirit and principles of the present application should be included in the scope of the present application.

What is claimed is:

1. A method for processing a display panel, comprising the following steps of:
preparing a substrate;
forming a first metal layer on the substrate;
forming a light shielding layer attached to the substrate at a lateral side of the first metal layer;
forming an insulation layer on the first metal layer, the light shielding layer and the substrate, wherein the first metal layer and the light shielding layer are each disposed between the insulation layer and the substrate;
forming a semiconductor layer on the insulation layer;
forming a second metal layer on the semiconductor layer, wherein the semiconductor layer is disposed between the insulation layer and the second metal layer;
processing the second metal layer and the semiconductor layer to form a channel, wherein the channel divides the second metal layer into a source layer and a drain layer;
forming a protection layer on the source layer, the drain layer and an inner wall of the channel; and
forming a conductive layer on the protection layer, such that the conductive layer is connected with the source layer or the drain layer.

2. The method according to claim 1, wherein the light shielding layer is formed by jet printing on the lateral side of the first metal layer through an Inkjet technology.

3. The method according to claim 1, wherein the light shielding layer comprises a first light shielding layer formed on one side of the first metal layer through jet printing and a second light shielding layer formed on the other side of the first metal layer through jet printing.

4. The method according to claim 3, wherein the thickness of the first light shielding layer is smaller than the thickness of the first metal layer, and the thickness of the second light shielding layer is smaller than the thickness of the first metal layer.

5. The method according to claim 1, wherein the first metal layer is processed to form a gate electrode through processes of exposure and development.

6. The method according to claim 1, wherein the materials of the first metal layer and the second metal layer are one or more type of aluminum and molybdenum.

7. The method according to claim 6, wherein when the material of the first metal layer is aluminum, the thickness of the first metal layer ranges from 3240 angstrom to 3960 angstrom.

8. The method according to claim 6, wherein when the material of the second metal layer is aluminum, the thickness of the second metal layer ranges from 3240 angstrom to 3960 angstrom.

9. The method according to claim 6, wherein when the material of the first metal layer is molybdenum, the thickness of the first metal layer ranges from 450 angstrom to 550 angstrom.

10. The method according to claim 6, wherein when the material of the second metal layer is molybdenum, the thickness of the first metal layer ranges from 450 angstrom to 550 angstrom.

11. The method according to claim 1, wherein the material of the insulation layer comprises silicon oxide and/or silicon nitride.

12. The method according to claim 1, wherein the protection layer is formed through a chemical vapor deposition film formation technology.

13. The method according to claim 1, wherein the material of the protection layer comprises silicon oxide and/or silicon nitride.

14. The method according to claim 1, wherein the semiconductor layer comprises an active layer formed on the insulation layer and an ohmic contact layer formed on the active layer, wherein the active layer is disposed between the insulation layer and the ohmic contact layer.

15. The method according to claim 14, wherein the material of the active layer is amorphous silicon, polycrystalline silicon or metal-oxide semiconductor.

16. The method according to claim 1, wherein the substrate is a glass substrate.

17. The method according to claim 16, wherein the thickness of the glass substrate ranges from 0.52 mm to 0.58 mm.

18. A display panel, comprising: a substrate; a first metal layer disposed on the substrate; a light shielding layer jetted on a side of the first metal layer; an insulation layer disposed on the first metal layer, the light shielding layer and the substrate; a semiconductor layer disposed on the insulation layer; a second metal layer disposed on the semiconductor layer; a protection layer disposed on the second metal layer; and a conductive layer disposed on the protection layer.
